(19) United States
(12) Patent Application Publication
(10) Pub. No.: US 2013/0154714 A1
(43) Pub. Date: Jun. 20, 2013

(54) CURRENT-MODE SAMPLE AND HOLD FOR DEAD TIME CONTROL OF SWITCHED MODE REGULATORS

(71) Applicant: Conexant Systems, Inc., Newport Beach, CA (US)

(72) Inventors: Brian W. Friend, Carlsbad, CA (US); Kyehyung Lee, Irvine, CA (US)

(73) Assignee: CONEXANT SYSTEMS, INC., Newport Beach, CA (US)

(21) Appl. No.: 13/719,577

(22) Filed: Dec. 19, 2012

Related U.S. Application Data
(60) Provisional application No. 61/578,213, filed on Dec. 20, 2011.

(51) Int. Cl. H03K 17/56

(52) U.S. Cl. CPC H03K 17/56
USPC 327/362

(57) ABSTRACT

A system for current mode sample and hold, comprising a first PMOS transistor configured to generate a current to be sampled. A diode-connected NMOS transistor coupled to the first PMOS transistor and configured to receive the current. A switch coupled to the diode-connected NMOS transistor and configured to sample a gate-source voltage of the diode-connected NMOS transistor. A capacitor coupled to the switch and configured to stored the gate-source voltage of the diode-connected NMOS transistor. A second NMOS transistor coupled to the capacitor and configured to generate a current equal to the sampled current value.

### RELATED CASES

The present application claims priority to U.S. Provisional application 61/578,213, filed Dec. 20, 2011, entitled “CURRENT-MODE SAMPLE AND HOLD FOR DEAD TIME CONTROL OF SWITCHED MODE REGULATORS,” which is hereby incorporated by reference for all purposes.

### TECHNICAL FIELD

The present disclosure pertains generally to switched mode regulators, and more specifically to a current-mode sample and hold circuit for dead time control of switched mode regulators.

### BACKGROUND OF THE INVENTION

In a switched-mode regulator, “dead-time” refers to the time between when the output PMOS switch turns off and the output NMOS switch turns on. The output switching node capacitance requires a certain amount of time to discharge, which is proportional to the regulator load current. Internal monitoring circuitry is typically used to provide a current signal which is scaled copy of the regulator load current. To optimize the dead-time (and minimize the efficiency loss due to dead-time), the delay is controlled.

### SUMMARY OF THE INVENTION

A system for current mode sample and hold, comprising a first PMOS transistor configured to generate a current to be sampled. A diode-connected NMOS transistor coupled to the first PMOS transistor and configured to receive the current. A switch coupled to the diode-connected NMOS transistor and configured to sample a gate-source voltage of the diode-connected NMOS transistor. A capacitor coupled to the switch and configured to stored the gate-source voltage of the diode-connected NMOS transistor. A second NMOS transistor coupled to the capacitor and configured to generate a current equal to the sampled current value.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a system for using a current mode sample and hold circuit in a switched mode regulator in accordance with an exemplary embodiment of the present invention;

FIG. 2 is a diagram of a system for current mode sample and hold in accordance with an exemplary embodiment of the present invention;

FIG. 3 is a diagram of an algorithm for current mode sample and hold in accordance with an exemplary embodiment of the present invention;

FIGS. 4A and 4B are a diagram of a system for current mode sample and hold in accordance with an exemplary embodiment of the present invention; and

FIG. 5 is a diagram of a system for using sampled current information to adjust the internal loop compensation network to cancel out a load pole effectively that is load current dependent, in accordance with an exemplary embodiment of the present invention.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

Power efficiency is an important performance metric for switched mode regulators. For example, the internal circuitry of the regulator should consume as little power as possible. Nevertheless, a complex assortment of internal housekeeping circuitry has been used to monitor performance and to control modes of operation of state of switched mode regulators.

There are several operating characteristics of switched mode regulators that degrade efficiency. One of these characteristics is the time duration from when the PMOS output power switch turns off to when the NMOS power switch turns on. This time-duration is called the ‘dead-time,’ which refers to the time between when the output PMOS switch turns off and the NMOS switch turns on.

The output switching node capacitance requires an amount of time to discharge that is proportional to the regulator load current. Internal monitoring circuitry can be used to provide a current signal which is a scaled copy of the regulator load current. In order to optimize the dead-time (and minimize the efficiency loss due to dead-time), the delay can be controlled through analog means, with dead-time delay circuitry that makes use of the scaled output load current to control the dead-time delay.

It is desirable to keep the dead-time as small as possible, since during that time, a parasitic body diode can conduct current from ground through the inductor to the output load. The forward-biased body diode V_{BE} and the current that is conducted constitute a power loss that can be avoided, such as by turning on the NMOS stitch as soon as possible (and minimizing the dead-time) to lower the voltage drop from a forward-biased diode V_{BE} (˜0.7v), to that of the NMOS power switch V_{DS} (˜0.1V), thus resulting in a reduction in power loss and improvement in efficiency.

The minimum amount of time that the NMOS switch can be turned on is limited by how long it takes the output switching node to turn off. This amount of time is proportional to the load current being delivered during that particular switching cycle. Other monitoring circuitry provides a scaled-copy of the load current called the ‘load-sense’ current, which can be used to control the non-overlapping dead-time. Previously, other solutions have taken the load-sense current and converted it to a voltage, so that it can be sampled and held with a commonly used voltage-mode sample and hold circuit. The sampled and held voltage copy of the load sense current is then converted back to current mode to control a current-starved delay element circuit to control the dead-time.

Dead-time delay control circuitry can be implemented with controllable current-starved inverter delays, where the delay control can have a fixed component and a variable component. The variable component can be derived from the ‘scaled’ load current information. In order for the ‘scaled’ load current signal to be used, it should be sampled and held constant for each switch mode regulator cycle. Sampling of this load current information is performed with a sample and hold circuit.

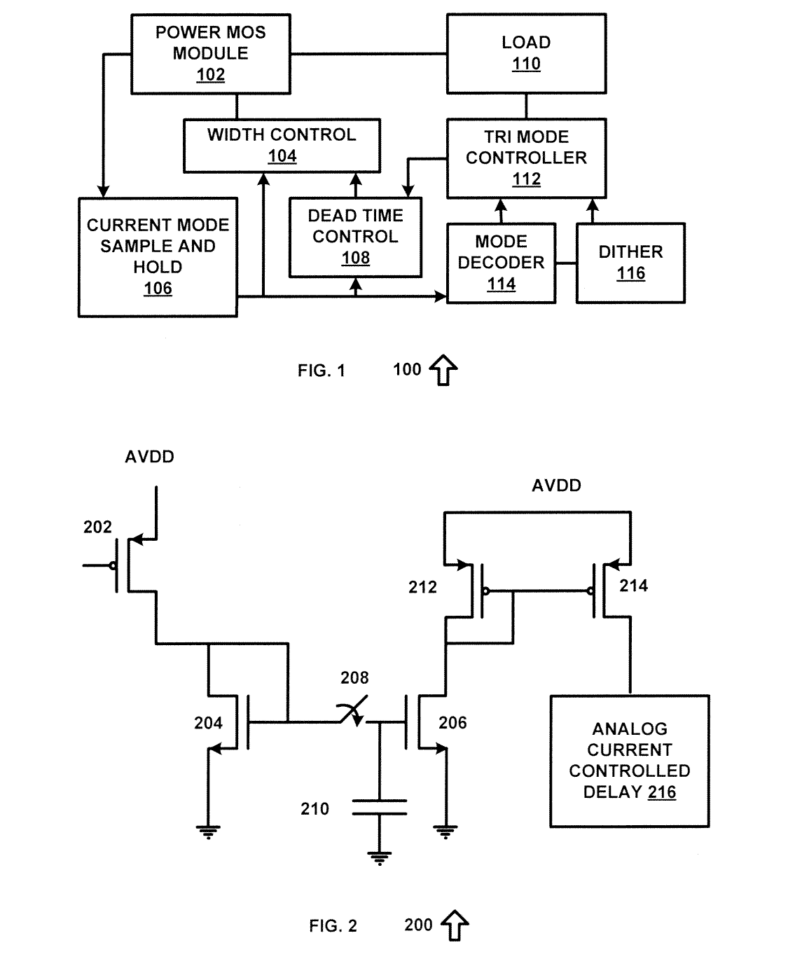

FIG. 1 is a diagram of a system 100 for using a current mode sample and hold circuit in a switched mode regulator in accordance with an exemplary embodiment of the present invention. System 100 includes power MOS module 102, width control 104, current mode sample and hold 106, dead time control 108, tri-mode controller 112, mode decoder 114 and dither 116, each of which can be implemented in hardware or a suitable combination of hardware and software. As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications or on two or more processors, or other suitable software structures. In one exemplary embodiment, software can include one or more lines of code or other suitable software structures operating in a general purpose software application, such as an operating system, and one or more lines of code or other suitable software structures operating in a specific purpose software application.

Power MOS module 102 includes NMOS and PMOS power switches. These switches are turned on by pulses having a predetermined pulse width, where the on state of the switches must not overlap in order to prevent damage. However, because the on state of the switches is also a function of the load, the pulse width cannot be static, but must vary as a function of the load. The time duration from when the PMOS output power switch turns off to when the NMOS power switch turns on is called the “dead-time.” It is generally desirable to keep the dead-time as small as possible, since during that time, a parasitic body diode can conduct current from ground through the inductor to the output load. A forward-biased body diode V_{BE} and the current that is conducted through it constitute a power loss, which can be avoided as discussed herein. Turning on the NMOS power switch as soon as possible (and minimizing the dead-time) lowers the voltage drop from a forward-biased diode V_{BE} (˜0.7v), to that of the NMOS power switch V_{DS} (˜0.1V), thus resulting in a reduction in power loss and improvement in efficiency.

Width control 104 receives inputs from current mode sample and hold 106 and dead time control 108 and generates width control for the pulses generated by power MOS module 102, and otherwise drives the operation of the NMOS and PMOS power switches.

Current mode sample and hold 106 receives output current sensing signals from power MOS module 102 and generates a held current output. Current mode sample and hold 106 avoids the need to convert a sampled current to a voltage for sampling and holding, and instead uses a current sampling circuit that provides improved efficiency.

Dead time control 108 receives outputs from current mode sample and hold 106 and tri-mode controller 112 and generates an output to width control 104 to reduce the amount of dead time between when a PMOS output power switch of power MOS module 102 turns off to when the NMOS power switch turns on. As previously discussed, the pulse width is a function of the load being provided by the power MOS module 102.

Tri-mode controller 112 receives an output from mode decoder 114 and dither 166 and generates pulse width modulation, dithering skip modulation and pulse frequency modulation control signals.

Mode decoder 114 and dither 116 receive an output from current mode sample and hold 106 and generate dithering skip pulses and other suitable outputs for tri-mode controller 112.

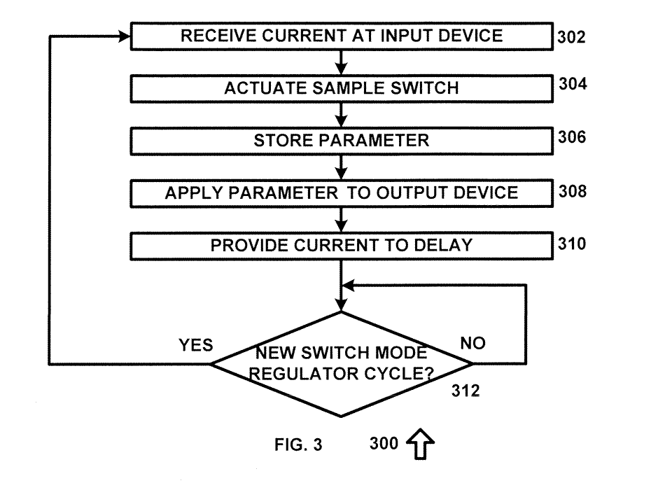

FIG. 2 is a diagram of a system 200 for current mode sample and hold in accordance with an exemplary embodiment of the present invention. System 200 includes PMOS transistor 202, which generates a current that is provided to diode-connected NMOS transistor 104. In one exemplary embodiment, PMOS transistor 202 can be a part of a power MOS module or other suitable devices that provides load current data for use by a current mode sample and hold circuit. Switch 208 is used to sample the gate-source voltage of NMOS transistor 204, which is stored in capacitor 210. NMOS transistor 206 generates a current equal to the sampled current value, because the gate-source voltage applied to the gate of NMOS transistor 206 is equal to the gate-source voltage of NMOS transistor 204. Diode-connected PMOS transistor 212 and PMOS transistor 214 mirror the sampled current and provide the current to analog current controlled delay 216. In one exemplary embodiment, analog current controlled delay 216 can be a part of a dead time control circuit or other suitable circuits for adjusting a pulse width or dead time between pulses for a power MOS module or other suitable devices.

In operation, system provides for current mode sample and hold for use in a switched mode regulator, which eliminates the need to convert a sampled current value to a voltage, to store the voltage, and then to convert the voltage back to a current value. By using diode-connected matched FET devices, the gate voltage of an input device (which corresponds to the current flowing through the device) can be stored and used to set the gate voltage of an output device, so as to allo for current mode sample and hold.

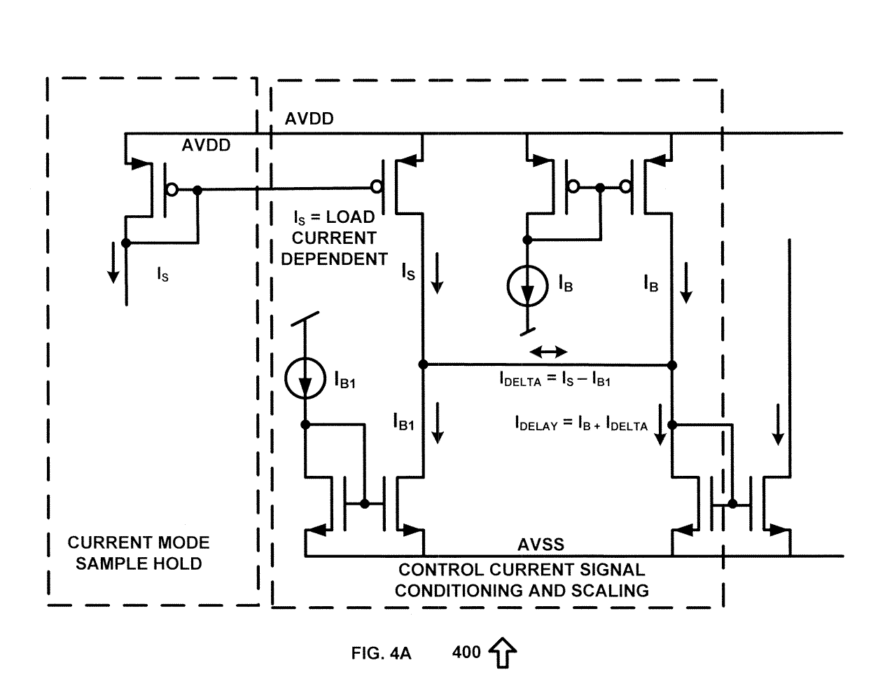

FIG. 3 is a diagram of an algorithm 300 for current mode sample and hold in accordance with an exemplary embodiment of the present invention. Algorithm 300 can be implemented in hardware or a suitable combination of hardware and software.

Algorithm 300 begins at 302, where a current to be sampled is received at an input device. In one exemplary embodiment, the input transistor can be a diode-connected NFET transistor, a diode-connected PFET transistor or other suitable devices. The algorithm then proceeds to 304.

At 304, a sample switch is actuated. In one exemplary embodiment, a sample control can be generated based on input voltage and current values from a power MOS module, based on timing data, or based on other suitable data, in order to sample a current value, such as a load current value or other suitable current values. The algorithm then proceeds to 306.

At 306, a parameter is stored, such as a gate to source voltage or other suitable parameters. In one exemplary embodiment, a diode-connected NFET can be used as the input device and a gate-source voltage of the diode-connected NFET can be stored, such as by using a storage capacitance that is connected in parallel with the diode-connected NFET. The algorithm then proceeds to 308, where the parameter is applied to an output device, such as NFET The algorithm then proceeds to 310 where a current is provided to a delay. The algorithm then proceeds to 312 where it is determined whether a new switch mode regulator cycle is occurring. If a new cycle is occurring, the algorithm returns to 302, otherwise, the algorithm remains at 312.

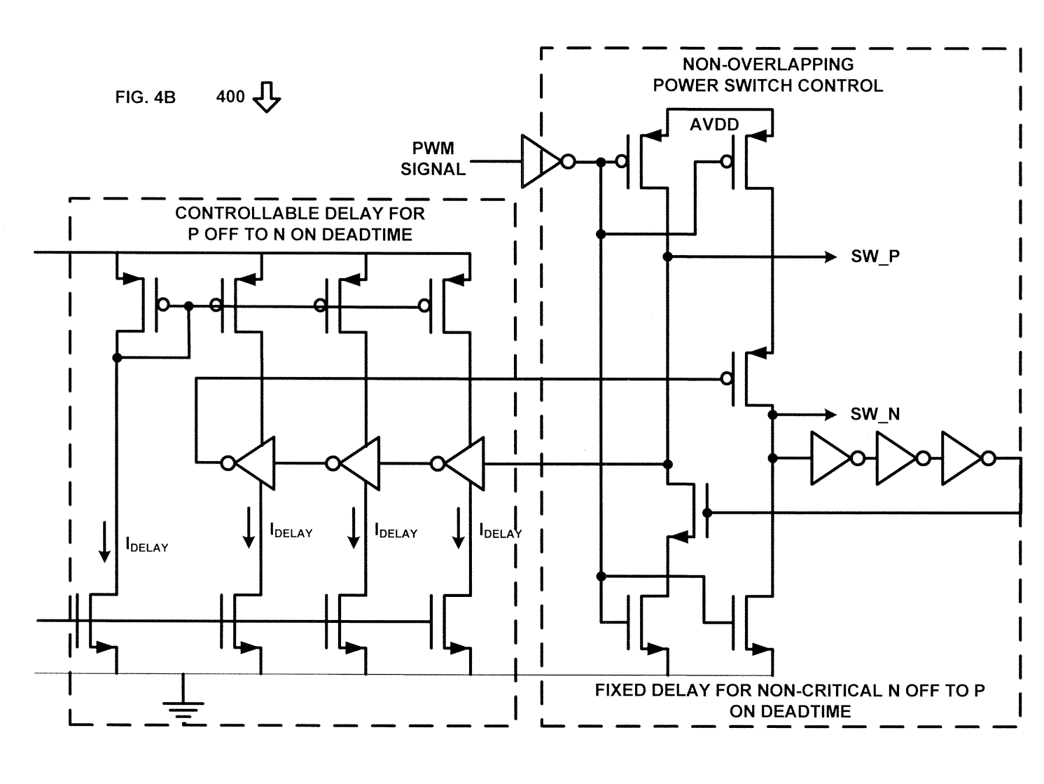

FIGS. 4A and 4B are a diagram of a system 400 for current mode sample and hold in accordance with an exemplary embodiment of the present invention. System 400 includes a current mode sample and hold stage, a control current signal conditioning and scaling stage, a controllable delay for P off to N on dead time stage, a non-overlapping power switch control stage and a fixed delay for non-critical N off to P on dead time stage.

A diode-connected PMOS transistor in the current mode sample and hold stage is connected to a PMOS transistor in the a control current signal conditioning and scaling stage, which generates a current that is provided to an NMOS transistor.

The control current signal conditioning and scaling stage receives the load dependent current I_{S} and generates a conditioned and scaled delay current I_{DELAY} that equals I_{S} plus a first bias current I_{B} and minus a second bias current I_{B1}. The bias currents I_{B} and I_{B1} are used to provide control current signal condition and scaling. The magnitude of I_{B} should be such that at an average load current, the variable P_{OFF} to N_{ON} is optimized for maximum power efficiency. The minimum value of I_{DELTA} is set by the value of I_{B1}, and the maximum value is set by I_{S}-I_{B1}. For symmetrical delay variation, I_{B1} can be half of the maximum value of I_{S}. The value of I_{DELTA} is typically a small fraction of I_{DELAY}, and appropriate for the variation of P_{OFF} to N_{ON} delay as a function of regulator load current.

The controllable delay for P off to N on dead time stage provides a suitable number of controllable delay stages for processing the sampled current, and provides inputs to the non-overlapping power switch control stage, which generates the NFET and PFET control signals. A stage for generating a fixed delay for non-critical N off to P on dead time is also provided.

In operation, system 400 provides for current mode sample and hold for use in a switched mode regulator, which eliminates the need to convert a sampled current value to a voltage, to store the voltage, and then to convert the voltage back to a current value. By using diode-connected matched FET devices, the gate voltage of an input device (which corresponds to the current flowing through the device) can be stored and used to set the gate voltage of an output device, so as to allow for current mode sample and hold.

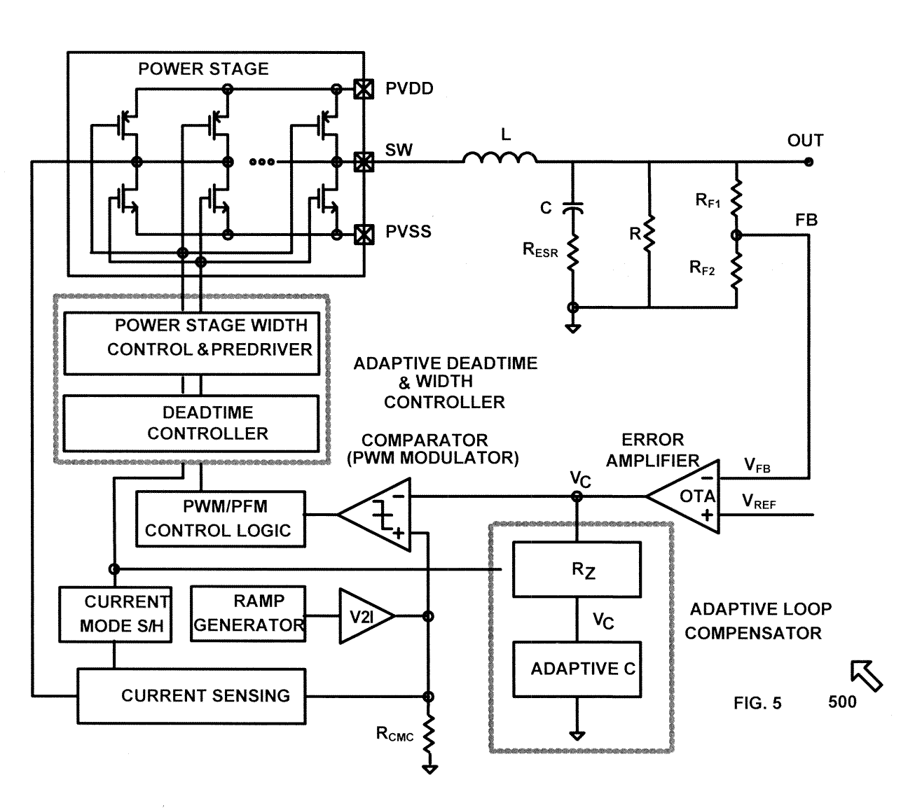

FIG. 5 is a diagram of a system 500 for using sampled current information to adjust the internal loop compensation network to cancel out a load pole effectively that is load current dependent, in accordance with an exemplary embodiment of the present invention. System 500 is similar to system 100, but includes an adaptive loop compensator in place of tri-mode controller 112 and other associated components of system 100. The disclosed current mode sample and hold circuit provides sampled current information to the adaptive loop compensator to cancel out a load current dependent load pole.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for current mode sample and hold, comprising:
a first PMOS transistor configured to generate a current to be sampled;
a diode-connected NMOS transistor coupled to the first PMOS transistor and configured to receive the current;
a switch coupled to the diode-connected NMOS transistor and configured to sample a gate-source voltage of the diode-connected NMOS transistor;
a capacitor coupled to the switch and configured to stored the gate-source voltage of the diode-connected NMOS transistor;
a second NMOS transistor coupled to the capacitor and configured to generate a current equal to the sampled current value.

2. The system of claim 1 further comprising a diode-connected PMOS transistor and a second PMOS transistor configured to generate the sampled current and provide the sampled current to analog current controlled delay.

3. The system or claim 1 wherein the first PMOS transistor is coupled to a power module, and the current to be sampled is derived from a current of the power module.

4. The system of claim 3 further comprising a dead time control configured to receive the sampled current value and to generate dead time control data for generation of control pulses for PMOS transistors and NMOS transistors of a power module.

5. The system of claim 4 further comprising a width control coupled to the power module and the dead time control, the width control configured to receive the dead time control data to control a pulse width of the control pulses for the PMOS transistors and the NMOS transistors of the power module.

6. The system of claim 3 further comprising:
a load coupled to the power module; and
an adaptive loop compensator coupled to the load and configured to cancel out a load current dependent load pole.

7. A method for current mode sample and hold, comprising:
receiving a current to be sampled at an input device;
actuating a sample switch to sample a current value; and
storing a parameter using a storage capacitance that is connected in parallel with the input device.

8. The method of claim 7 wherein the input device comprises a diode-connected NFET transistor.

9. The method of claim 7 wherein the input device comprises a diode-connected PFET transistor.

10. The method of claim 7 wherein actuating the sample switch comprises actuating the sample switch based on an input voltage from a power MOS module.

11. The method of claim 7 wherein actuating the sample switch comprises actuating the sample switch based on an input current value from a power MOS module.

12. The method of claim 7 wherein actuating the sample switch comprises actuating the sample switch based on timing data.

13. The hod of claim wherein actuating the sample switch to sample the current value comprises actuating the sample switch to sample a load current value.

14. The method of claim 7 wherein storing the parameter using the storage capacitance that is connected in parallel with the input device comprises storing a gate to source voltage of a diode-connected NFET.

15. A system for current mode sample and hold control of a power module, comprising:
means for current mode sample and hold coupled to the power module and configured to receive a current to be sampled from the power module;
means for control current signal conditioning and scaling coupled to the means for current mode sample and hold and configured to condition and scale a sampled current value; and
means for providing a controllable delay for P off to N on dead time control coupled to the means for control current signal conditioning and scaling and to the power module and configured to receive the conditioned and scaled sampled current value and to generate controllable delay data for turning one or more PMOS transistor of the power module off and one or more NMOS transistor of the power module on.

16. The system of claim 15 wherein the means for current mode sample and hold comprises a diode-connected PFET.

17. The system of claim 15 wherein the means for control current signal conditioning and scaling comprises a PFET coupled to a first NFET current mirror with a first bias current source I_{B1} and coupled to a pair of PFETs connected as a current mirror and driven by second bias current source I_{B}, an also coupled to a second NFET current mirror.

18. The system of claim 15 wherein the means for providing the controllable delay for P off to N on dead time control comprises a plurality of inverter stages coupled to NFET/PFET pairs.

19. The system of claim 15 further comprising means for non-overlapping power switch control.

20. The system of claim 15 further comprising means for providing a fixed delay for non-critical N off to P on dead time control.
